(19) United States
(12) Patent Application Publication
(10) Pub. No.: US 2025/0321627 A1
(43) Pub. Date: Oct. 16, 2025

(54) TESTING APPARATUSES, TESTING DEVICES, TESTING METHODS AND STORAGE MEDIUMS

(71) Applicant: YANGTZE MEMORY TECHNOLOGIES CO., LTD., Wuhan (CN)

(72) Inventors: Xiong XU, Wuhan (CN); Zhenyu LEI, Wuhan (CN); Zhihua TANG, Wuhan (CN); Lei DING, Wuhan (CN); ShuJie HE, Wuhan (CN)

(21) Appl. No.: 19/022,550

(22) Filed: Jan. 15, 2025

(30) Foreign Application Priority Data
Apr. 10, 2024 (CN) 202410435268.1

(51) Int. Cl. G06F 1/20

(52) U.S. Cl. CPC G06F 1/20

(57) ABSTRACT

Examples of the present disclosure provide testing apparatuses, testing devices, testing methods and storage mediums. An example testing apparatus includes a first communication interface, a control circuit, a second communication interface and a thermostatic device. The first port of the control circuit is coupled to the first communication interface. The second port of the control circuit is coupled to the second communication interface, and the second communication port is further connected to the device under test. The third port of the control circuit is coupled to the thermostatic device. The thermostatic device includes a cavity in which the device under test is placed. The control circuit is configured to control the temperature inside the cavity of the thermostatic device and implement information transmission between the first communication interface and the second communication interface.

### CROSS-REFERENCE TO RELATED APPLICATIONS

The present application claims the benefit of priority to China Application No. 202410435268.1, filed on Apr. 10, 2024, the content of which is incorporated herein by reference in its entirety.

### TECHNICAL FIELD

The present disclosure relates to the field of electronic technology, and relates to but is not limited to a testing apparatus, testing device, testing method and storage medium.

### BACKGROUND

In the production process of Solid State Disk (SSD), the working performance, stability, and reliability of SSD are closely related to the ambient temperature and the temperature inside the SSD. Whether in the test stages of the SSD product verification or the factory production, there are many scenarios where it is required to control the ambient temperature and then control the temperature inside the hard disk to conduct testing at a certain temperature, such as Reliability Demonstration Test (RDT), Ongoing Reliability Test (ORT), aging test, stress test, etc.

### SUMMARY

Examples of the present disclosure propose a testing apparatus, testing device, testing method and storage medium. In an aspect, the testing apparatus includes: a first communication interface, a control circuit, a second communication interface and a thermostatic device; a first port of the control circuit is coupled to the first communication interface; a second port of the control circuit is coupled to the second communication interface, and the second communication port is further connected to the device under test; a third port of the control circuit is coupled to the thermostatic device, the thermostatic device includes a cavity in which the device under test is placed; where, the control circuit is configured to control the temperature inside the cavity of the thermostatic device and implement information transmission between the first communication interface and the second communication interface.

In some examples, the control circuit includes a temperature regulation circuit and a conversion circuit; the temperature regulation circuit is coupled to the first port and the third port, and is configured to parse the command information received by the first port, and send the parsed command information to the thermostatic device through the third port; the conversion circuit is coupled to the first port and the second port, and is configured to process the data information received by the first port and send the processed data information to the second port; or the conversion circuit is configured to process the data information received by the second port and send the processed data information to the first port.

In some examples, the thermostatic device further includes: temperature measuring circuit coupled to each of the third port, the temperature regulation circuit and the cavity of the thermostatic device, and is configured to receive the parsed command information and obtain the temperatures at different positions in the cavity of the thermostatic device based on the parsed command information, and send multiple temperatures to the temperature regulation circuit.

In some examples, the temperature regulation circuit is further configured to receive the multiple temperatures, and parse the multiple temperatures and the command information received by the first port with a Proportional Integral Derivative (PID) algorithm.

In some examples, the thermostatic device further includes: a heating circuit coupled to the third port and the cavity of the thermostatic device, and configured to receive the parsed command information and to raise the temperature inside the cavity of the thermostatic device based on the parsed command information; a cooling circuit coupled to the third port and the cavity of the thermostatic device, and configured to receive the parsed command information and reduce the temperature inside the cavity of the thermostatic device based on the parsed command information.

In some examples, the testing apparatus further includes: a connector; the first port of the connector is connected to the third port of the control circuit, the second port of the connector is connected to the thermostatic device, the first port of the connector is detachable from the second port of the connector.

In some examples, the first communication interface and the second communication interface require different formats for data information; in some examples, the control circuit is configured to process the data information transmitted between the first communication interface and the second communication interface, so that the processed data information adapts to the format requirements of the first communication interface/second communication interface.

In some examples, the first communication interface includes a PCIe interface, and the second communication interface includes an M.2 interface.

In some examples, the third port of the control circuit includes a general-purpose input/output port (GPIO); where the universal input/output port is coupled to the thermostatic device through an Inter-Integrated Circuit (IIC).

In some examples, the cavity volume of the thermostatic device is greater than or equal to 200 ml.

In some examples, the control circuit further includes a fourth port; the fourth port is to input a voltage; the control circuit is further configured to regulate the voltage to provide a voltage environment required for testing of the device under test.

In some examples, the device under test includes a solid state drive.

In another aspect, an example of the present disclosure provides a testing device, including: a power generating device configured to provide voltage; a testing apparatus, including: a first communication interface, a control circuit, a second communication interface and a thermostatic device; the first port of the control circuit is coupled to the first communication interface; the second port of the control circuit is coupled to the second communication interface, and the second communication port is further connected to the device under test; the third port of the control circuit is coupled to the thermostatic device, the thermostatic device includes a cavity in which the device under test is placed; the fourth port of the control circuit is connected to the power generating device; where, the control circuit is configured to control the temperature inside the cavity of the thermostatic device, regulate the voltage provided by the power generating device to provide the voltage environment required for testing of the device under test, and implement information transmission between the first communication interface and the second communication interface.

In another aspect, an example of the present disclosure provides a testing method, the testing method includes: placing the device under test in the cavity of the thermostatic device of the testing apparatus; sending a test instruction to the control circuit of the testing apparatus; the third port of the control circuit is coupled to the thermostatic device; the control circuit, in response to the test instruction, controls the temperature inside the cavity of the thermostatic device, and obtains various information for the device under test at different temperatures; and the control circuit, in response to the test instruction, implements information transmission among the first communication interface, the second communication interface and the device under test; the first communication interface is coupled to the first port of the control circuit, the second communication interface is coupled to the second port of the control circuit, and the second communication interface is further connected to the device under test.

In some examples, the control circuit includes a temperature regulation circuit and a conversion circuit; the methods includes: the temperature regulation circuit parses the command information received by the first port, and sends the parsed command information to the thermostatic device through the third port; the conversion circuit processes the data information received by the first port and sends the processed data information to the second port; or processes the data information received by the second port and sends the processed data information to the first port.

In some examples, the thermostatic device further includes a temperature measuring circuit, the method further includes: the temperature measuring circuit receives the parsed command information and obtains the temperatures at different positions in the cavity of the thermostatic device based on the parsed command information, and sends multiple temperatures to the temperature regulation circuit.

In some examples, the method further includes: the temperature regulation circuit receives the multiple temperatures, and parses the multiple temperatures and the command information received by the first port with a Proportional Integral Derivative (PID) algorithm.

In some examples, the thermostatic device further includes: a heating circuit and a cooling circuit; the method further includes: by the heating circuit, receiving the parsed command information and raising the temperature inside the cavity of the thermostatic device based on the parsed command information; by the cooling circuit, receiving the parsed command information and reducing the temperature inside the cavity of the thermostatic device based on the parsed command information.

In some examples, the testing apparatus further includes: a connector located between the third port of the control circuit and the thermostatic device, the first port of the connector is detachable from the second port of the connector.

In some examples, the control circuit further includes a fourth port connected to a power generating device; the method further includes: by the control circuit, regulating the voltage generated by the power generating device to provide the voltage environment required for testing of the device under test.

In another aspect, the present disclosure provides a storage medium having executable instructions stored on, which, when executed by a testing device, may implement the operations of the testing methods described in the examples of the present disclosure described above.

### BRIEF DESCRIPTION OF THE DRAWINGS

FIG. 1 is a schematic structural diagram of a testing apparatus provided by an example of the present disclosure.

FIG. 2 is a schematic structural diagram of a device under test provided by an example of the present disclosure.

FIG. 3 is a schematic structural diagram of a testing apparatus provided by another example of the present disclosure.

FIG. 4 is a schematic structural diagram of a testing apparatus including a connector provided by an example of the present disclosure.

FIG. 5 is a schematic diagram of the connection between the testing device and the power generating device provided by an example of the present disclosure.

FIG. 6 is a schematic flowchart of the operations of a testing method provided by an example of the present disclosure.

FIG. 7 is a schematic diagram of a testing apparatus provided by an example of the present disclosure.

### DETAILED DESCRIPTION

In order to make the technical solutions and advantages of the examples of the present disclosure clearer, the technical solutions of the present disclosure will be further described in detail below with reference to the accompanying drawings and examples. Although examples of the present disclosure are shown in the accompanying drawings, it should be understood that the present disclosure may be implemented in various forms and should not be limited to the examples set forth herein. Rather, these examples are provided so that the present disclosure can be more thoroughly understood and the scope of the present disclosure can be fully conveyed to those skilled in the art.

The present disclosure is described in more detail, by way of example, in the following paragraphs with reference to the accompanying drawings. The advantages and features of the present disclosure will become more apparent from the following description and claims. It should be noted that the accompanying drawings are in a very simplified form and use imprecise proportions, and are only to conveniently and clearly assist in describing the examples of the present disclosure.

It will be understood that the meanings of “on,” “on top of,” and “over” in this disclosure should be read in the broadest manner, such that “on” does not only mean “on” something without intervening features or layers in between (e.g., directly on something), but also includes being “on” something with intervening features or layers in between.

Additionally, for convenience of description, spatially relative terms such as “on,” “on top of,” “over,” “up,” “upper,” etc., may be used herein to describe the relationship of one element or feature to another element or feature as illustrated. The spatially relative terms are intended to encompass different orientations of the device in use or operation in addition to the orientation depicted in the accompanying drawings. The device may be otherwise oriented (rotated 90 degrees or at other orientations) and the spatially relative descriptors used herein may be interpreted accordingly.

In an example of the present disclosure, the term “substrate” refers to a material onto which subsequent material layers are added. The substrate itself may be patterned. Materials added on top of the substrate may be patterned or may remain unpatterned. Furthermore, the substrate may include a wide array of semiconductor materials, such as silicon, silicon germanium, germanium, arsenide, indium phosphide, etc. Alternatively, the substrate may be made from an electrically non-conductive material, such as a glass, a plastic, or a sapphire wafer.

In an example of the present disclosure, the term “layer” refers to a material portion including a region with a thickness. A layer may extend over the entirety of the underlying or overlying structure, or may have an extent that is less than the extent of the underlying or overlying structure. Further, a layer may be a region of a homogeneous or inhomogeneous continuous structure that has a thickness less than the thickness of the continuous structure. For example, a layer may be located between any set of horizontal planes between, or a layer may be between any horizontal plane at the top surface and bottom surface of the continuous structure. A layer may extend horizontally, vertically, and/or along an inclined surface. A layer may include multiple sublayers. For example, an interconnect layer may include one or more conductor and contact sublayers (in which interconnect lines and/or via contacts are formed), and one or more dielectric sublayers.

In examples of the present disclosure, terms “first”, “second”, etc., are to distinguish similar objects and are not necessarily to describe a specific order or sequence.

During the R&D and testing phase of an SSD, testers require to frequently verify firmware logic and test script logic, and observe the status and ambient temperature of the SSD in real time, while at present, most solutions to this problem are to put the SSD into a centrally managed thermostat, the thermostatic device is to provide a constant and stable environment to ensure the accuracy of experimental data when testing/verifying the SSD. When it is required to test the impact of ambient temperature on SSD test data, a specialized person is required to set the temperature to change the external environment of the SSD, and to collect and feedback the test data of the SSD after cooling down. However, in one aspect, due to the cumbersome process of temperature setting and data feedback, testers cannot directly and quickly control the temperature and check the status of the SSD in a timely manner. In another aspect, testers cannot directly obtain test data of the SSD at different temperatures.

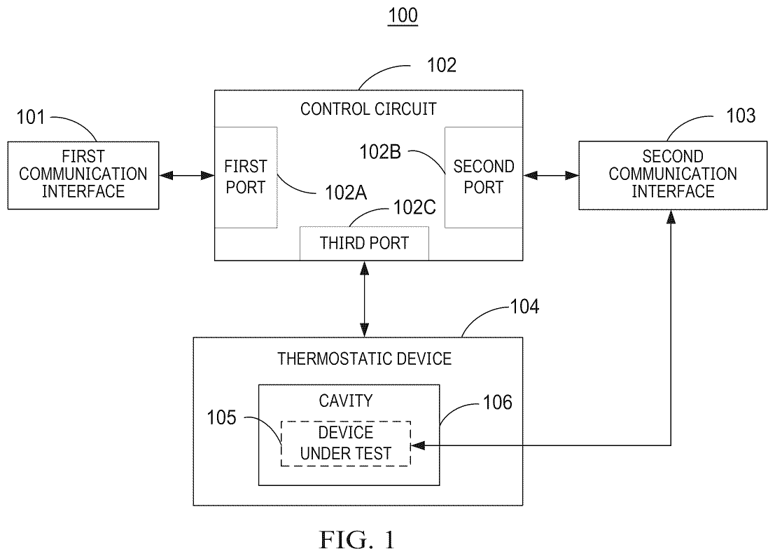

Based on one or more of the problems described above, an example of the present disclosure proposes a testing apparatus. Referring to FIG. 1, FIG. 1 is a schematic structural diagram of a testing apparatus 100 illustrated in an example of the present disclosure. As shown in FIG. 1, the testing apparatus 100 includes: a first communication interface 101, a control circuit 102, a second communication interface 103 and a thermostatic device 104. The control circuit 102 may include multiple ports, where the first port 102a of the control circuit is coupled to the first communication interface 101; the second port 102b of the control circuit is coupled to the second communication interface 103, and the third port 102c of the control circuit is coupled to the thermostatic device 104. In addition, the second communication interface 103 is also connected to the device under test 105; the thermostatic device 104 includes a cavity 106 for placing the device under test 105. During actual operation, the control circuit 102 is configured to control the temperature inside the cavity 106 of the thermostatic device and implement information transmission between the first communication interface 101 and the second communication interface 103.

In some examples, the first communication interface 101 and the second communication interface 103 may be of the same or different types; here, taking the first communication interface 101 and the second communication interface 103 being of different types as an example, in some examples, taking the first communication interface 101 and the second communication interface 103 requiring different formats for data information as an example. Thus, when the data information is interacted between the first communication interface 101 and the second communication interface 103, the control circuit 102 is to process the data information between the first communication interface 101 and the second communication interface 103, so that the processed data information is adapted to the format requirements of the first communication interface 101, or adapted to the format requirements of the second communication interface 103.

In some examples, the first communication interface 101 is also connected to the upper computer, the upper computer may be to issue a control command (including data information), and the control command is to instruct to store the data information into the device under test. At this point, the control command (including data information) is sent to the control circuit 102 through the first communication interface 101 and the first port 102a of the control circuit; the control circuit 102, after receiving the control command (including data information), process the data information in response to the control command, the processed data information may adapt to the format requirements of the second communication interface 103. Next, the control circuit 102 sends the processed data information to the device under test 105 through the second port 102b of the control circuit and the second communication interface 103 to store the data information in the device under test 105.

In other examples, the upper computer may be to issue another control command, and the other control command is to instruct to obtain data information in the device under test. At this point, the other control command is sent to the control circuit 102 through the first communication interface 101 and the first port 102a of the control circuit, the control circuit 102, after receiving the other control command, in response to the other control command, obtains data information from the device under test 105 through the second communication interface 103 and the second port 102b of the control circuit, and the control circuit 102, after obtaining the data information, processes the data information and the processed data information may adapt to the first communication interface 101. Next, the control circuit 102 then sends the processed data information to the upper computer through the first port 102a of the control circuit and the first communication interface 101.

Thus, the control circuit 102 may implement information transmission between the first communication interface 101 and the second communication interface 103 when the first communication interface 101 and the second communication interface 103 require different formats for data information. In some examples, the first communication interface 101 includes a PCIe interface, and the second communication interface 103 includes an M.2 interface.

In the example of the present disclosure described above, the second communication interface 103 is also connected to the device under test 105, the device under test 105 may be placed inside the cavity 106 of the thermostatic device, and the control circuit 102 may be to control the temperature inside the cavity 106 of the thermostatic device to achieve the purpose of controlling/adjusting the ambient temperature of the device under test 105. The control circuit 102 may implement the interaction between the first communication interface 101 (or the upper computer) and the thermostatic device 104 through the first port 102a of the control circuit and the third port 102c of the control circuit.

Based on this, when the device under test 105 is placed inside the cavity of the thermostatic device 104, information transmission between the first communication interface 101 (or upper computer) and the thermostatic device 104 may be implemented through the first port 102a of the control circuit 102 and the third port 102c of the control circuit 102 to control/adjust the ambient temperature of the device under test 105. Meanwhile, based on the control command of the upper computer, information transmission between the first communication interface 101 (or upper computer) and the device under test 105 may also be implemented through the first port 102a of the control circuit 102 and the second port 102b of the control circuit 102, so as to implement the storing/retrieving of data. For example, based on the testing apparatus described in the examples of the present disclosure described above, the device under test 105 may be tested at different temperatures to obtain various information for the device under test 105 at different temperatures. Thus, the test performance of the device under test 105 may be improved and the test efficiency may be improved.

In some examples, the device under test 105 may include a solid state drive (SSD), a Universal Flash Storage (UFS), an Embedded Multi Media Card (eMMC), and other devices with storage devices and storage control devices. Here and below, the device under test 105 is a solid-state drive (SSD) as an example. However, it should be understood that the following description of the solid state drive SSD is only to illustrate the present disclosure and is not to limit the scope of the present disclosure.

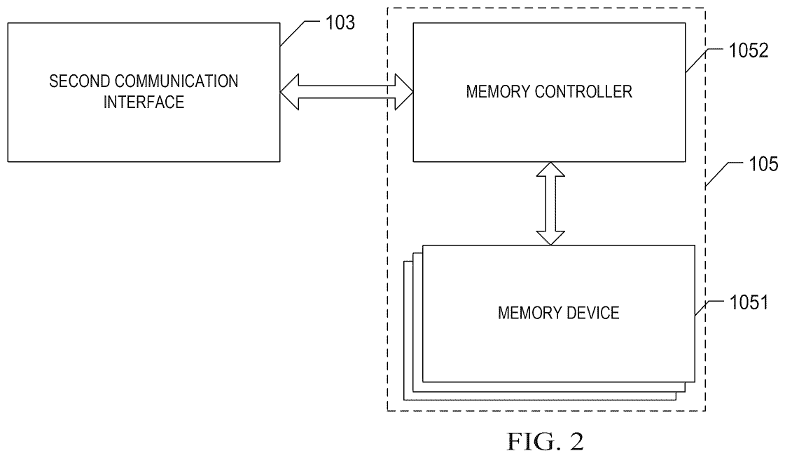

In some examples, referring to FIG. 2, which is a schematic structural diagram of a device under test 105 being a solid state drive (SSD) provided by an example of the present disclosure, where the device under test 105 includes one or more memory devices 1051 and a memory controller 1052, the memory controller 1052 may be coupled to memory device 1051 in any suitable manner and configured to control memory device 1051, and the memory controller 1052 may manage data stored in the memory device 1051. As shown in FIG. 2, the memory controller 1052 is connected to the second communication interface 103 and is to implement the transmission of data in the memory device 1051.

In some examples, memory controller 1052 may be configured to control operations of memory device 1051, e.g., read, erase and program operations. Memory controller 1052 may also be configured to manage various functions related to data stored or to be stored in memory device 1051, including but not limited to bad block management, garbage collection, logical-to-physical address translation, wear leveling, etc. In some examples, memory controller 1052 is also configured to process error correction code (ECC) related to data read from or written to memory device 1051. The memory controller 1052 may also perform any other suitable functions, e.g., formatting the memory device 1051. The memory controller 1052 may communicate with external devices (e.g., the second communication interface 103, a host computer, etc.) according to a particular communication protocol. For example, the memory controller 1052 may communicate with an external device through at least one of various interface protocols, e.g., USB protocol, MMC protocol, Peripheral Component Interconnect (PCI) protocol, PCI Express (PCI-E) protocol, advanced Technology Attachment (ATA) protocol, Serial ATA protocol, Parallel ATA protocol, Small Computer Small Interface (SCSI) protocol, Enhanced Small Disk Interface (ESDI) protocol, Integrated Drive Electronics (IDE) protocol, Firewire protocol, etc.

In some examples, the volume of the cavity 106 of the thermostatic device 104 may be selected and set according to actual demands. In an example of the present disclosure, the volume of the cavity 106 of the thermostatic device 104 is slightly larger than the overall volume of the device under test 105, e.g., the volume of the cavity 106 of the thermostatic device 104 is greater than or equal to 200 ml. For example, the thermostatic device 104 described in the example of the present disclosure is small in size, easy to control, easy to carry, and has low manufacturing cost.

In some examples, the control circuit 102 may include a microcontroller unit (MCU), also known as a single chip microcomputer or a single chip microcomputer, which may perform different combined controls in different application scenarios.

In some examples, the third port 102c of the control circuit 102 may include a general-purpose input/output port GPIO; where the general-purpose input/output port GPIO may be coupled to the thermostatic device 104 through an integrated circuit bus IIC. Additionally, the first port 102a of the control circuit 102 and the second port 102b of the control circuit 102 may also be general-purpose input/output ports GPIO. In some examples, the first port 102a of the control circuit 102 may also be any other suitable port adapted to the first communication interface 101, and the second port 102b of the control circuit 102 may also be any other suitable port adapted to the second communication interface 103, which is not limited in this disclosure.

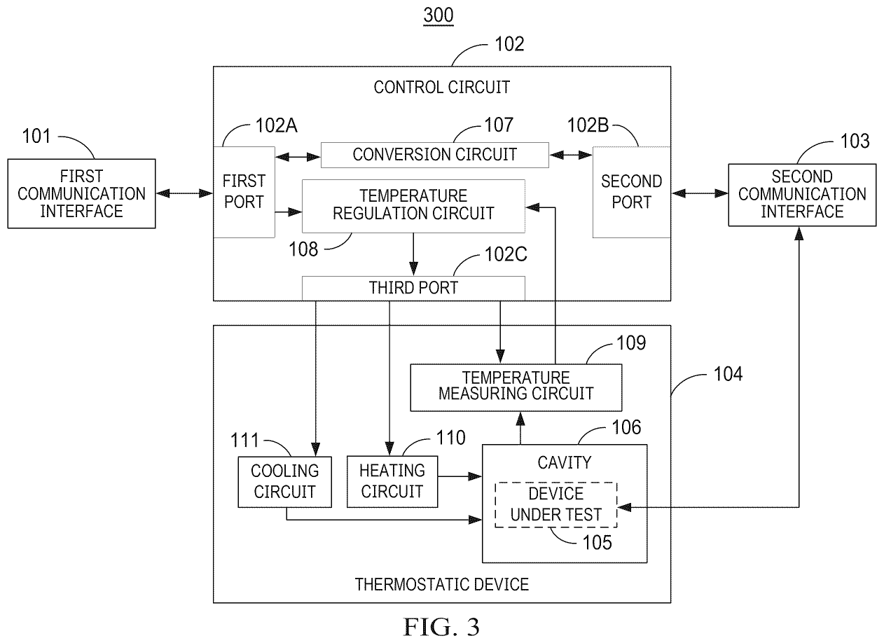

In some examples, referring to FIG. 3, which is a schematic structural diagram of a testing apparatus 300 provided by another example of the present disclosure; where the control circuit 102 may include a temperature regulation circuit 108 and a conversion circuit 107; where the temperature regulation circuit 108 is coupled to the first port 102a of the control circuit 102 and the third port 102c of the control circuit 102, and is configured to parse the command information received by the first port 102a of the control circuit 102, and send the parsed command information to the thermostatic device 104 through the third port 102c of the control circuit 102. The conversion circuit 107 is coupled to the first port 102a of the control circuit 102 and the second port 102b of the control circuit 102, and is configured to process the data information received by the first port 102a of the control circuit 102, and send the processed data information to the second port 102b of the control circuit 102; alternatively, the conversion circuit 107 is configured to process the data information received by the second port 102b of the control circuit 102, and send the processed data information to the first port 102a of the control circuit 102.

In an example of the present disclosure, the conversion circuit 107 may be to convert the format requirements of the data information to adapt to the different format requirements of the first communication interface 101 and the second communication interface 103 for the data information; and the conversion circuit 107 may also perform other forms of conversion, which is not limited in the present disclosure. The temperature regulation circuit 108 may be to parse the received command information, and send a temperature adjusting instruction to the thermostatic device 104 based on results of the parsing, the thermostatic device 104 may, in response to the temperature adjusting instruction, control the power output of the thermostatic device 104 to adjust or control the temperature inside the cavity 106 of the thermostat, thereby adjusting/changing the ambient temperature of the device under test 105.

The data information and command information described in the above examples are only to distinguish information transmitted in different paths, and are not to limit the content of the information.

In some examples, referring to FIG. 3, the thermostatic device 104 further includes a temperature measuring circuit 109 for testing the temperature inside the cavity 106 of the thermostatic device 104 and feeding back the temperature information to the temperature regulation circuit 108. Where the temperature measuring circuit 109 is coupled to each of the third port 102c of the control circuit 102, the temperature regulation circuit 108 and the cavity 106 of the thermostatic device 104, and is configured to receive the parsed command information and obtain the temperatures at different positions in the cavity of the thermostatic device 104 based on the parsed command information, and send multiple temperatures to the temperature regulation circuit 108.

In some examples, the temperature measuring circuit 109 measures the temperatures at different positions inside the cavity 106 of the thermostatic device 104 based on the parsed command information to obtain the temperatures at different positions in the cavity 106 of the thermostatic device 104, the multiple temperatures are then fed back to the temperature regulation circuit 108, and the temperature regulation circuit 108 analyzes the feedback of the temperature information and determines whether to adjust the temperature in the cavity 106 of the thermostatic device 104.

In some examples, the temperature regulation circuit 108 may also directly change/adjust the temperatures at different positions within the cavity 106 of the thermostatic device 104 based on the received command information.

In some examples, the temperature measuring circuit 109 may include, but is not limited to, a digital temperature sensor and a switching MOS transistor. The IIC communication protocol is a simple and effective serial communication protocol that may be widely used for data transmission between various electronic devices, the temperature measuring circuit 109 may perform data transmission after multi-point temperature measuring through the IIC bus, such that the temperature may be collected accurately and the accuracy of the data may be improved.

In some examples, the temperature regulation circuit 108, after receiving the multiple temperatures, may parse/analyze the multiple temperatures and the command information received by the first port 102a of the control circuit 102 with a Proportional Integral Derivative (PID) algorithm. In some examples, the temperature regulation circuit 108, after receiving the feedback of the multiple temperatures, performs analysis and processing based on the multiple temperatures and the command information (including the temperature setting value issued by the upper computer) received by the first port 102a of the control circuit 102; if the result of the analysis and processing shows that the multiple temperatures are different from the temperature setting values issued by the upper computer, then a temperature adjusting instruction is sent to other devices (e.g., a heating circuit, a cooling circuit) in the thermostatic device 104 to adjust the temperature inside the cavity 106 of the thermostatic device 104, such as raising or reducing. If the result of the analysis and processing shows that the multiple temperatures are the same as the temperature setting values issued by the upper computer, a temperature maintenance instruction may be sent to other devices (e.g., a heating circuit, a cooling circuit) in the thermostatic device 104 to continue to maintain the current ambient temperature of the device under test 105. Alternatively, the temperature regulation circuit 108 does not send an instruction so that the temperature inside the cavity 106 of the thermostatic device 104 remains at the current ambient temperature.

For example, the temperature regulation circuit sends the parsed command information to the heating circuit or the cooling circuit based on the parse results of the command information received by the first ports of the multiple temperature and control circuits, the parsed command information is to instruct the heating circuit to raise the temperature inside the cavity of the thermostatic device 104, or to instruct the cooling circuit to reduce the temperature inside the cavity of the thermostatic device 104.

In some examples, the PID algorithm controls according to the proportion (P), integral (I) and differential (D) of the deviation during the temperature control operation, it has the advantages of simple principle, easy example, wide application, independent control parameters, and relatively simple parameter selection. In an example of the present disclosure, precise control of the temperature inside the cavity of the thermostatic device may be implemented by combining the PID algorithm with Pulse-width modulation (PWM). During actual operation, the combination of PID algorithm and PWM technology may be implemented by collecting data, calculating errors, calculating proportional terms, calculating integral terms, calculating differential terms, weighted addition, and updating PWM duty cycle, etc. Thus, the temperature inside the cavity of the thermostatic device may be accurately controlled, making the test data of the device under test more accurate.

Based on this, referring to FIG. 3, the thermostatic device 104 also includes: a heating circuit 110 and a cooling circuit 111. The heating circuit 110 is to raise the temperature inside the cavity 106 of the thermostatic device; the cooling circuit 111 is to reduce the temperature inside the cavity 106 of the thermostatic device 104. The heating circuit 110 is coupled to the third port 102c of the control circuit 102 and the cavity 106 of the thermostatic device 104. When the multiple temperatures fed back by the temperature measuring circuit 109 are lower than the temperature setting values issued by the host computer, the heating circuit 110 is configured to receive a temperature adjusting instruction and raise the temperature inside the cavity 106 of the thermostatic device 104 based on the analyzed command information, so that the adjusted temperature complies with the temperature setting value issued by the host computer. The cooling circuit 111 is coupled to the third port 102c of the control circuit 102 and the cavity 106 of the thermostatic device 104. When the multiple temperatures fed back by the temperature measuring circuit 109 are higher than the temperature setting values issued by the host computer, the cooling circuit 111 is configured to receive a temperature adjusting instruction and reduce the temperature inside the cavity 106 of the thermostatic device 104 based on the analyzed command information, so that the adjusted temperature complies with the temperature setting value issued by the upper computer.

Here, the heating circuit 110 and the cooling circuit 111 are two independent temperature regulation circuits; e.g., the heating circuit 110 may include a ceramic heating piece, which may use DC heating, and the ceramic heating piece is small in size, high in power, and has a fast heating rate; it may also include a PTC heating piece (thermistor), etc. The cooling circuit 111 may include a cooling fan, which may reduce the temperature by increasing air flow.

In some examples, the thermostatic device 104 may not only include the apparatus described above, but may also include a humidity sensor, an electric stress sensor, etc., which will not be described in detail in the present disclosure.

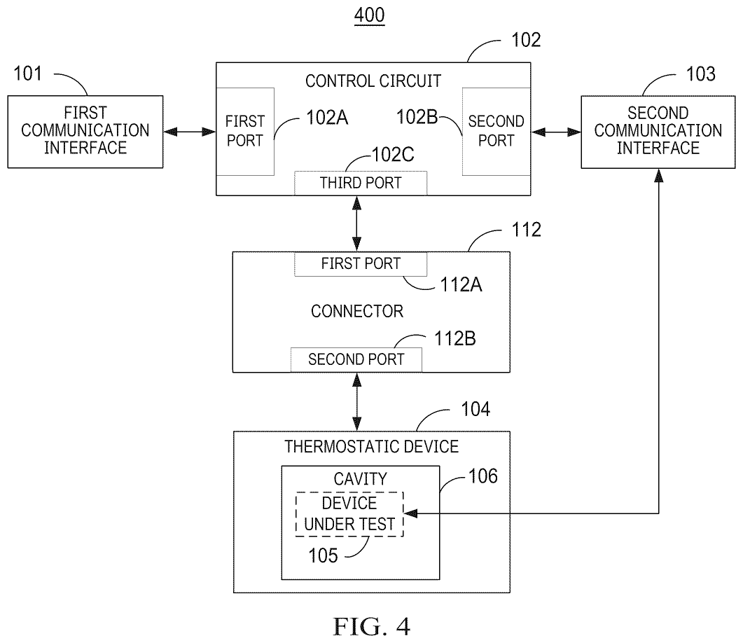

In some examples, referring to FIG. 4, which is a schematic structural diagram of a testing apparatus 400 including a connector (e.g., plug and socket) provided by an example of the present disclosure, where the testing apparatus 400 further includes a connector 112 located between the control circuit 102 and the thermostatic device 104 for connecting the control circuit 102 and the thermostatic device 104. Here, the connector 112 may include multiple ports, e.g., a first port 112a of the connector 112 and a second port 112b of the connector 112, where the first port 112a of the connector 112 is connected to the third port 102c of the control circuit 102, the second port 112b of the connector 112 is connected to the thermostatic device 104 to implement the connection and signal transmission between the control circuit 102 and the thermostatic device 104. In an example of the present disclosure, the first port 112a of the connector 112 is detachable from the second port 112b of the connector 112, so that the thermostatic device 104 is detachable/separable from the control circuit 102, furthermore, when the thermostatic device 104 is not required to the control circuit 102, the thermostatic device 104 and the control circuit 102 may be separated through the connector 112 to improve the portability and convenience of the testing device. For example, the thermostatic device 104 and the control circuit 102 may be combined or separated through the connector 112, and the two are plug-and-play, which is convenient and fast.

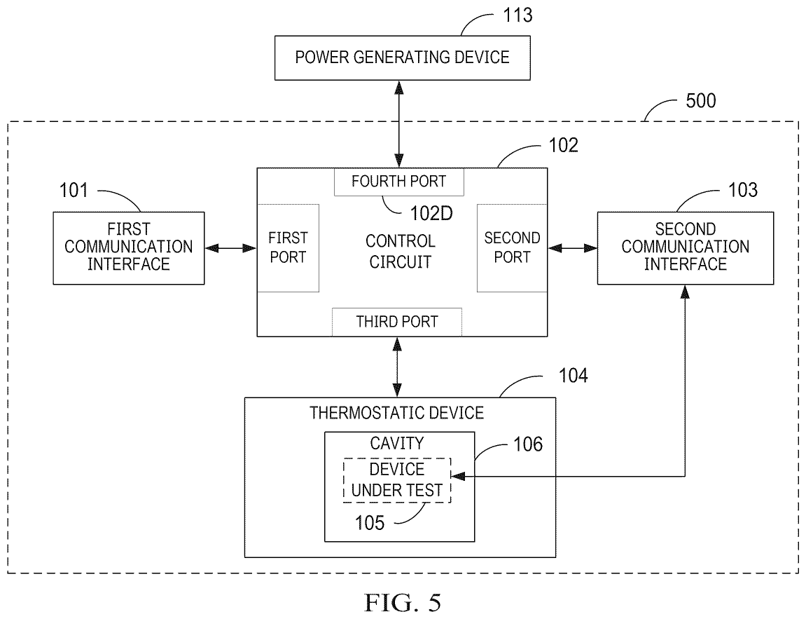

In some examples, referring to FIG. 5, which is a schematic diagram of the connection between the testing apparatus 500 and the power generating device provided by an example of the present disclosure, the control circuit 102 also includes a fourth port 102d. The fourth port 102d is to input a voltage, and the control circuit 102 is also configured to regulate the voltage received by the fourth port 102d. In some examples, the fourth port 102d of the control circuit 102 is connected to an external device, such as the power generating device 113. The control circuit 102 is also configured to regulate the voltage generated by the external device, such as the power generating device 113, to provide the device under test 105 with the voltage environment required for testing.

In some examples, when there is a mismatch between the voltage generated by the power generating device 113 and the test voltage required by the device 105 under test, the voltage generated by the power generating device 113 may be regulated by the control circuit 102, so that the voltage generated by the power generating device 113 matches the test voltage required by the device under test 105, and the test voltage is provided to the device under test 105. In some examples, due to devices under test being different, the test voltages applied to different devices under test may also be different, for a same device under test, the test voltages applied to the device under test may also be different at different test periods, in the example of the present disclosure, the power generating device 113 may be regulated through the control circuit 102 to generate different test voltages according to different requirements.

Based on this, in examples of the present disclosure, different ports of the control circuit 102 are respectively connected to the first communication interface, the second communication interface, and the thermostatic device 104, such that the interconnection among multiple devices may be controlled through the control circuit 102 to implement mutual influence and interaction among multiple devices. For example, when the device under test 105 is placed inside the cavity of the thermostatic device 104, information transmission between the first communication interface and the thermostatic device may be implemented through the first port of the control circuit 102 and the third port of the control circuit to control/adjust the ambient temperature of the device under test 1015. Meanwhile, information transmission between the first communication interface and the device under test 105 may also be implemented through the first port of the control circuit 102 and the second port of the control circuit 102, so as to implement the storing/retrieving of data in the device under test 105. Furthermore, based on the testing apparatus described in the examples of the present disclosure described above, the device under test 105 may be tested at different temperatures to obtain various information for the device under test 105 at different temperatures. Thus, the test performance of the device under test 105 may be improved, the test efficiency and the efficiency of development of the SSD firmware may be improved, and the R&D cost may be reduced.

In addition, in some examples of the present disclosure, the thermostatic device 104 may also be separated from the control circuit 102 through a connector 112. For example, the thermostatic device 104 may be used as an independent electronic accessory, which is detachable and plug-and-play, thereby improving the convenience of the testing device. In another aspect, the cavity volume of the thermostatic device 104 is small (greater than or equal to 200 ml), this may reduce the overall volume of the testing apparatus, thereby improving convenience and reducing manufacturing costs. In yet another aspect, the output information for the control circuit 102 is adjusted in real time through PID algorithm and PWM control, and then the power output of the heating circuit (e.g., the ceramic heating plate in the heating circuit) and the cooling circuit (e.g., the cooling fan in the cooling circuit) are controlled to achieve precise control of the ambient temperature of the device under test 105 and improve the accuracy of test data.

Based on the testing apparatus described above, an example of the present disclosure further provides a testing device, including: a power generating device configured to provide a voltage; and a testing apparatus, including: a first communication interface, a control circuit, a second communication interface and a thermostatic device; the first port of the control circuit is coupled to the first communication interface; the second port of the control circuit is coupled to the second communication interface, and the second communication port is further connected to the device under test; the third port of the control circuit is coupled to the thermostatic device, the thermostatic device includes a cavity in which the device under test is placed; the fourth port of the control circuit is connected to the power generating device; where, the control circuit is configured to control the temperature inside the cavity of the thermostatic device, regulate the voltage provided by the power generating device to provide the voltage environment required for testing of the device under test, and implement information transmission between the first communication interface and the second communication interface. As mentioned before, the power generating device may provide the test voltages required for the same or different types of devices under test.

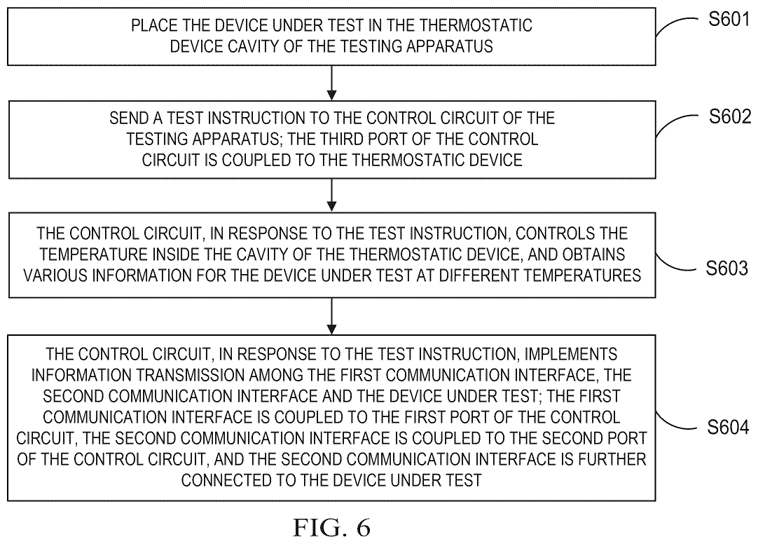

Based on the testing apparatus described above, an example of the present disclosure further provides a testing method. Referring to FIG. 6, FIG. 6 is a schematic flowchart of the operations of a testing method provided by an example of the present disclosure. The testing method includes the following operations:

Operation S601: place the device under test in the cavity of the thermostatic device of the testing apparatus.

Operation S602: send a test instruction to the control circuit of the testing apparatus; the third port of the control circuit is coupled to the thermostatic device.

Operation S603: the control circuit, in response to the test instruction, controls the temperature inside the cavity of the thermostatic device, and obtains various information for the device under test at different temperatures.

Operation S604: the control circuit, in response to the test instruction, implements information transmission among the first communication interface, the second communication interface and the device under test; the first communication interface is coupled to the first port of the control circuit, the second communication interface is coupled to the second port of the control circuit, and the second communication interface is further connected to the device under test.

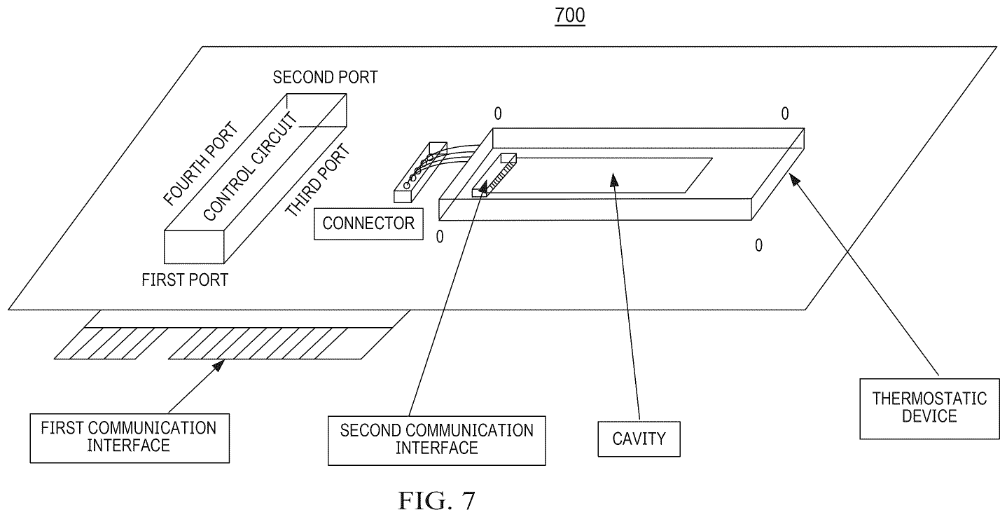

FIG. 7 is a schematic diagram of a testing apparatus 700 provided by an example of the present disclosure, the testing method of the testing apparatus will be described below in conjunction with FIG. 6 and FIG. 7.

In operation S601, the testing apparatus 700 includes a first communication interface, a control circuit, a second communication interface and a thermostatic device, the first port of the control circuit is coupled to the first communication interface, and the second port of the control circuit is coupled to the second communication interface, the third port of the control circuit is coupled to the thermostatic device, e.g., the device under test is an SSD, the SSD is connected to the second communication interface; the thermostatic device includes a cavity for placing the SSD. The first communication interface and the second communication interface may require the same format or different formats for data information.

In some examples, the first communication interface includes a PCIe interface and the second communication interface includes an M.2 interface. Each of the first port of the control circuit, the second port of the control circuit, and the third port of the control circuit may include, but are not limited to, general-purpose input/output ports GPIO. Where, the third port of the control circuit is coupled to the thermostatic device through the integrated circuit bus IIC.

In some examples, the cavity volume of the thermostatic device is greater than or equal to 200 ml.

In some examples, the device under test may include a solid state drive (SSD), a universal flash memory (UFS), an embedded multimedia card (eMMC), and other devices with storage devices and storage control devices. Here, the device under test is a solid-state drive (SSD) as an example.

In operation S602, the test instruction is to instruct the testing device to test the device under test, such as reliability verification test, product reliability test, aging test, stress test, etc. During the actual operation, the test command may be issued by the host device (e.g., an upper computer) or by other control device at the test site, which is not limited by this disclosure.

In operations S603 and S604, the control circuit performs a test operation on the device under test based on the test instruction. In examples of the present disclosure, when the first communication interface and the second communication interface require different formats for data information; the control circuit may process the data information transmitted between the first communication interface and the second communication interface, so that the processed data information adapts to the format requirements of the first communication interface/second communication interface.

In some examples, the control circuit includes a temperature regulation circuit and a conversion circuit; the temperature regulation circuit is coupled to the first port of the control circuit and the third port of the control circuit, and the conversion circuit is coupled to the first port of the control circuit and the second port of the control circuit, where the control circuit performing a test operation on the device under test based on the test instruction includes: the temperature regulation circuit parsing the command information received by the first port, and sending the parsed command information to the thermostatic device through the third port of the control circuit; the conversion circuit processing the data information received by the first port of the control circuit and sending the processed data information to the second port of the control circuit; or processing the data information received by the second port of the control circuit and sending the processed data information to the first port of the control circuit.

In some examples, the thermostatic device further includes a temperature measuring circuit, the temperature measuring circuit is coupled to the third port of the control circuit, the temperature regulation circuit, and the cavity of the thermostatic device; the method further includes: the temperature measuring circuit receiving the parsed command information and obtaining the temperatures at different positions in the cavity of the thermostatic device based on the parsed command information, and sending multiple temperatures to the temperature regulation circuit.

In some examples, the temperature regulation circuit, after receiving the multiple temperatures, parses the multiple temperatures and the command information received by the first port of the control circuit with a Proportional Integral Derivative (PID) algorithm.

In some examples, the thermostatic device further includes: a heating circuit and a cooling circuit, the heating circuit is coupled to the third port of the control circuit and the cavity of the thermostatic device, the cooling circuit is coupled to the third port of the control circuit and the cavity of the thermostatic device. The method further includes: the temperature regulation circuit sending the parsed command information to the heating circuit or the cooling circuit based on the parsing result of the multiple temperatures and the command information received by the first port of the control circuit. Next, the heating circuit receives the parsed command information and raises the temperature inside the cavity of the thermostatic device based on the parsed command information; or the cooling circuit receives the parsed command information and reduces the temperature inside the cavity of the thermostatic device based on the parsed command information.

In some examples, the testing apparatus further includes: a connector; the first port of the connector is connected to the third port of the control circuit, the second port of the connector is connected to the thermostatic device, the first port of the connector is detachable from the second port of the connector, such that the thermostatic device and the control circuit may be separated through the connector to improve the portability and convenience of the testing device.

In some examples, the control circuit further includes a fourth port; the fourth port of the control circuit is connected to the power generating device; the method further includes: the control circuit regulating the voltage generated by the power generating device to provide the voltage environment required for testing of the device under test.

The present disclosure further provides a storage medium having executable instructions stored thereon, which, when executed by a testing device, may implement the operations of the testing methods in the examples of the present disclosure described above.

In some examples, the storage medium may be memory such as Ferromagnetic Random Access Memory (FRAM), Read Only Memory (ROM), Programmable Read-Only Memory (PROM), Erasable Programmable Read-Only Memory (EPROM), Electrically Erasable Programmable Read-Only Memory (EEPROM), Flash Memory, Magnetic Surface Memory, Optical Disk, or Compact Disc Read-Only Memory (CD-ROM); or may also be various devices including one or any combination of the memory devices described above.

In some examples, executable instructions may take the form of a program, software, software module, script, or code, written in any form of programming language (including compiled or interpreted languages, or declarative or procedural languages), and may be deployed in any form, including as a stand-alone program or as a module, component, subroutine, or other unit suitable for use in a computing environment.

As an example, executable instructions may, but do not necessarily correspond to, files in a file system, and may be stored as part of a file holding other programs or data, e.g., one or more scripts stored in a Hyper Text Markup Language (HTML) document, stored in a single file specific to the program discussed, or stored in multiple collaborative files (e.g., a file that stores one or more modules, subroutines, or portions of code).

As examples, executable instructions may be deployed to execute on one computing device, or on multiple computing devices located at one location, or to execute on multiple computing devices distributed across multiple locations and interconnected by a communications network.

In addition, each functional unit in each example of the present disclosure may be integrated into one processing module, or each unit may be used as a single unit, or two or more units may be integrated into one unit; the integrated units described above may be implemented in the form of hardware, or in the form of hardware plus software functional units.

Those of ordinary skill in the art may understand that all or portions of the operations to implement the method examples described above may be completed by hardware related to program instructions, and the aforementioned program may be stored in a non-transitory, computer-readable storage medium, the program, when is executed, performs the operations including the method examples described above.

It should be noted that “first”, “second”, etc., are to distinguish similar objects and are not necessarily to describe a specific order or sequence.

Additionally, the technical solutions described in the examples of the present disclosure may be combined arbitrarily as long as there is no conflict.

The above descriptions is only preferred examples of the present disclosure and is not intended to limit the protection scope of the present disclosure.

What is claimed is:

1. A testing apparatus, comprising:
a first communication interface;
a second communication interface connected to a device under test;
a thermostatic device comprising a cavity in which the device under test is placed; and
a control circuit, wherein a first port of the control circuit is coupled to the first communication interface, a second port of the control circuit is coupled to the second communication interface, and a third port of the control circuit is coupled to the thermostatic device;
wherein, the control circuit is configured to:
control a temperature inside the cavity of the thermostatic device; and
implement information transmission between the first communication interface and the second communication interface.

2. The testing apparatus of claim 1, wherein the control circuit includes:
a temperature regulation circuit coupled to the first port and the third port, and configured to:
parse command information received by the first port, and
send the parsed command information to the thermostatic device through the third port; and
a conversion circuit coupled to the first port and the second port, wherein
the conversion circuit is configured to: process data information received by the first port and send the processed data information to the second port; or
the conversion circuit is configured to: process the data information received by the second port and send the processed data information to the first port.

3. The testing apparatus of claim 2, wherein the thermostatic device further includes:
a temperature measuring circuit coupled to each of the third port, the temperature regulation circuit and the cavity of the thermostatic device, and configured to:
receive the parsed command information;
obtain temperatures at different positions in the cavity of the thermostatic device based on the parsed command information; and
send the temperatures to the temperature regulation circuit.

4. The testing apparatus of claim 3, wherein the temperature regulation circuit is further configured to:
receive the temperatures; and
parse the temperatures and the command information received by the first port with a Proportional Integral Derivative (PID) algorithm.

5. The testing apparatus of claim 4, wherein the thermostatic device further includes:
a heating circuit coupled to the third port and the cavity of the thermostatic device, and configured to:
receive the parsed command information; and
raise the temperature inside the cavity of the thermostatic device based on the parsed command information; and
a cooling circuit coupled to the third port and the cavity of the thermostatic device, and configured to:
receive the parsed command information; and
reduce the temperature inside the cavity of the thermostatic device based on the parsed command information.

6. The testing apparatus of claim 1, wherein the testing apparatus further includes:
a connector, wherein a first port of the connector is connected to the third port of the control circuit, a second port of the connector is connected to the thermostatic device, and the first port of the connector is detachable from the second port of the connector.

7. The testing apparatus of claim 1, wherein the first communication interface and the second communication interface require different formats for data information; and
the control circuit is configured to process data information transmitted between the first communication interface and the second communication interface, so that the processed data information adapts to the format requirements of the first communication interface or the second communication interface.

8. The testing apparatus of claim 1, wherein the first communication interface includes a PCIe interface, and the second communication interface includes an M.2 interface.

9. The testing apparatus of claim 1, wherein the third port of the control circuit includes a general-purpose input/output port (GPIO); wherein the universal input/output port is coupled to the thermostatic device through an integrated circuit (IIC).

10. The testing apparatus of claim 1, wherein volume of the cavity of the thermostatic device is greater than or equal to 200 ml.

11. The testing apparatus of claim 1, wherein the control circuit further includes a fourth port to input a voltage, and the control circuit is further configured to: regulate the voltage to provide a voltage environment required for testing of the device under test.

12. The testing apparatus of claim 1, wherein the device under test includes a solid-state disk.

13. A testing device, comprising:
a power generating device configured to provide a voltage; and
a testing apparatus comprising:
a first communication interface;
a second communication interface connected to a device under test;
a thermostatic device comprising a cavity in which the device under test is placed; and
a control circuit, wherein a first port of the control circuit is coupled to the first communication interface, a second port of the control circuit is coupled to the second communication interface, a third port of the control circuit is coupled to the thermostatic device, a fourth port of the control circuit is connected to the power generating device;
wherein, the control circuit is configured to:
control a temperature inside the cavity of the thermostatic device;
regulate the voltage provided by the power generating device to provide a voltage environment required for testing of the device under test; and
implement information transmission between the first communication interface and the second communication interface.

14. The testing device of claim 13, wherein the control circuit includes:
a temperature regulation circuit coupled to the first port and the third port, and configured to:
parse command information received by the first port, and
send the parsed command information to the thermostatic device through the third port; and
a conversion circuit coupled to the first port and the second port, wherein
the conversion circuit is configured to: process data information received by the first port and send the processed data information to the second port; or
the conversion circuit is configured to: process the data information received by the second port and send the processed data information to the first port.

15. The testing device of claim 14, wherein the thermostatic device further includes:
a temperature measuring circuit coupled to each of the third port, the temperature regulation circuit and the cavity of the thermostatic device, and configured to:
receive the parsed command information;
obtain temperatures at different positions in the cavity of the thermostatic device based on the parsed command information; and
send the temperatures to the temperature regulation circuit.

16. The testing device of claim 15, wherein the temperature regulation circuit is further configured to:
receive the temperatures; and
parse the temperatures and the command information received by the first port with a Proportional Integral Derivative (PID) algorithm.

17. The testing device of claim 16, wherein the thermostatic device further includes:
a heating circuit coupled to the third port and the cavity of the thermostatic device, and configured to:
receive the parsed command information; and
raise the temperature inside the cavity of the thermostatic device based on the parsed command information; and
a cooling circuit coupled to the third port and the cavity of the thermostatic device, and configured to:
receive the parsed command information; and
reduce the temperature inside the cavity of the thermostatic device based on the parsed command information.

18. The testing device of claim 13, wherein the testing apparatus further includes:
a connector, wherein a first port of the connector is connected to the third port of the control circuit, a second port of the connector is connected to the thermostatic device, and the first port of the connector is detachable from the second port of the connector.

19. The testing device of claim 13, wherein the first communication interface and the second communication interface require different formats for data information; and
the control circuit is configured to: process data information transmitted between the first communication interface and the second communication interface, so that the processed data information adapts to the format requirements of the first communication interface or the second communication interface.

20. A testing method, comprising:
placing a device under test in a cavity of a thermostatic device of a testing apparatus;
sending a test instruction to a control circuit of the testing apparatus, wherein a third port of the control circuit is coupled to the thermostatic device;
by the control circuit, in response to the test instruction, controlling temperature inside the cavity of the thermostatic device, and obtaining various information for the device under test at different temperatures; and
by the control circuit, in response to the test instruction, implementing information transmission among a first communication interface, a second communication interface and the device under test;
wherein the first communication interface is coupled to a first port of the control circuit, the second communication interface is coupled to a second port of the control circuit, and the second communication interface is further connected to the device under test.
